(19) United States
(12) Patent Application Publication
(10) Pub. No.: US 2025/0210317 A1
(43) Pub. Date: Jun. 26, 2025

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: KOKUSAI ELECTRIC CORPORATION, Tokyo (JP)

(72) Inventors: Yasutoshi TSUBOTA, Toyama-shi (JP); Hiroki KISHIMOTO, Toyama-shi (JP)

(73) Assignee: KOKUSAI ELECTRIC CORPORATION, Tokyo (JP)

(21) Appl. No.: 19/073,636

(22) Filed: Mar. 7, 2025

Related U.S. Application Data
(63) Continuation of application No. PCT/JP2023/011918, filed on Mar. 24, 2023.

(30) Foreign Application Priority Data
Sep. 9, 2022 (JP) 2022-143753

(51) Int. Cl. H01J 37/32; H01L 21/02

(52) U.S. Cl. CPC H01J 37/32522; H01L 21/02247

(57) ABSTRACT

There is provided a technique that includes: (a) heating a process vessel with a predetermined thermal gradient without loading a process substrate in the process vessel; and (b) processing the process substrate after (a) with the process substrate loaded in the process vessel.

### CROSS-REFERENCE TO RELATED PATENT APPLICATION

This application is a bypass continuation application of PCT International Application No. PCT/JP2023/011918, filed on Mar. 24, 2023, in the WIPO, the international application being based upon and claiming the benefit of priority from Japanese Patent Application No. 2022-143753, filed on Sep. 9, 2022, in the Japanese Patent Office, the entire contents of which are hereby incorporated by reference.

### BACKGROUND

### 1. Field

The present disclosure relates to a substrate processing method, a method of manufacturing a semiconductor device, a non-transitory computer-readable recording medium and a substrate processing apparatus.

### 2. Related Art

According to some related arts, as a part of a manufacturing process of a semiconductor device, a step of pre-heating a process vessel may be performed before a substrate processing step is performed.

### SUMMARY

According to the present disclosure, there is provided a technique capable of suppressing a generation of particles in a process vessel.

According to an embodiment of the present disclosure, there is provided a technique that includes: (a) heating a process vessel with a predetermined thermal gradient without loading a process substrate in the process vessel; and (b) processing the process substrate after (a) with the process substrate loaded in the process vessel.

### BRIEF DESCRIPTION OF THE DRAWINGS

FIG. 1 is a diagram schematically illustrating a vertical cross-section of a substrate processing apparatus preferably used in one or more embodiments of the present disclosure.

FIG. 2 is a diagram schematically illustrating a principle of generating a plasma in the substrate processing apparatus preferably used in the embodiments of the present disclosure.

FIG. 3 is a block diagram schematically illustrating a configuration of a controller 221 and related components of the substrate processing apparatus preferably used in the embodiments of the present disclosure.

FIG. 4 is a flow chart schematically illustrating a processing step preferably used in the embodiments of the present disclosure.

FIG. 5 is a flow chart schematically illustrating a first step (pre-processing step) of the processing step preferably used in the embodiments of the present disclosure.

FIG. 6 is a flow chart schematically illustrating a second step (substrate processing step) of the processing step preferably used in the embodiments of the present disclosure.

FIG. 7 is a diagram schematically illustrating a vertical cross-section of a substrate processing apparatus preferably used in another embodiment of the present disclosure.

### DETAILED DESCRIPTION

### Embodiments of Present Disclosure

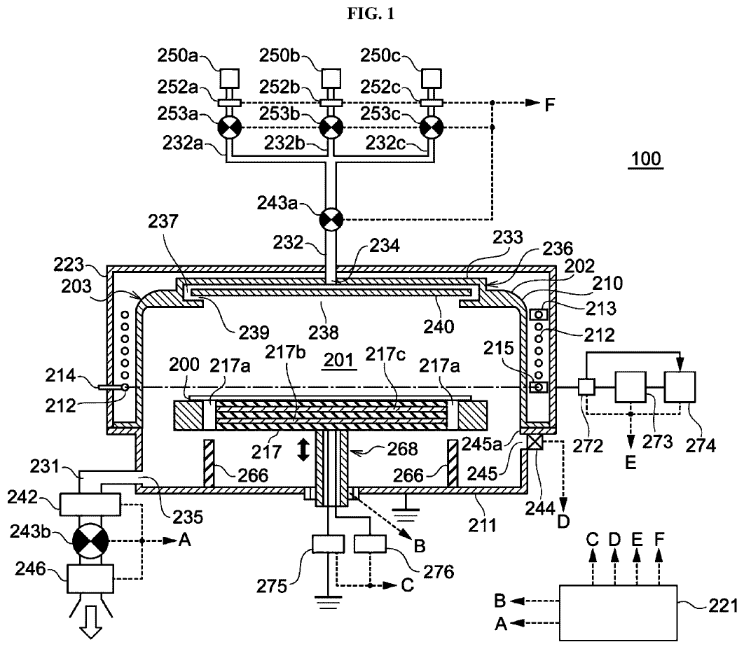

Hereinafter, one or more embodiments (hereinafter, also simply referred to as “embodiments”) according to the present disclosure will be described with reference to FIGS. 1 to 6. Further, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match.

### (1) Configuration of Substrate Processing Apparatus

Hereinafter, a configuration of a substrate processing apparatus 100 according to the embodiments of the present disclosure will be described below with reference to FIG. 1. The substrate processing apparatus 100 according to the present embodiments is configured to perform a nitridation process mainly on a base (such as an underlying layer) or a film formed on a surface of a substrate such as a wafer 200 described below.

### Process Chamber

As shown in FIG. 1, the substrate processing apparatus 100 includes a reaction furnace 202 in which the wafer 200 serving as a process substrate (that is, the substrate to be processed) is accommodated therein and in which the wafer 200 is processed by using a plasma. The reaction furnace 202 is provided with a process vessel 203 constituting a process chamber 201. The process vessel 203 may include a dome-shaped upper vessel 210 serving as a first vessel and a bowl-shaped lower vessel 211 serving as a second vessel. The process chamber 201 is formed by covering the lower vessel 211 by the upper vessel 210 thereon. For example, the upper vessel 210 is made of a non-metallic material such as aluminum oxide (Al₂O₃) and quartz (SiO₂), and the lower vessel 211 is made of a metal such as aluminum (Al).

In addition, a gate valve 244 serving as valve capable of opening and closing a loading/unloading port 245 is provided on a lower side wall of the lower vessel 211. When the gate valve 244 is open, the wafer 200 is capable of being transferred (loaded) into the process chamber 201 through the loading/unloading port 245 or capable of being transferred (unloaded) out of the process chamber 201 through the loading/unloading port 245. When the gate valve 244 is closed, the gate valve 244 maintains the process chamber 201 airtight.

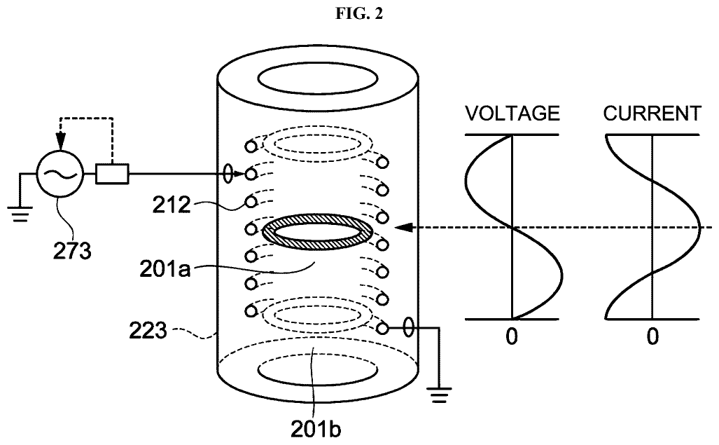

As shown in FIG. 2, the process chamber 201 may include a plasma generation space 201a and a substrate processing space 201b communicating with the plasma generation space 201a. The wafer 200 is processed in the substrate processing space 201b. The plasma generation space 201a is a space in which the plasma is generated. For example, the plasma generation space 201a refers to a space above a lower end of a resonance coil 212 (indicated by a dashed and dotted line in FIG. 1). On the other hand, the substrate processing space 201b is a space in which the wafer 200 is processed by plasma. For example, the substrate processing space 201b refers to a space below the lower end of the resonance coil 212.

### Susceptor

A susceptor 217 serving as a substrate mounting table on which the wafer 200 is placed is provided at a center of a bottom portion of the process chamber 201. The susceptor 217 is provided below the resonance coil 212 in the process chamber 201. For example, the susceptor 217 is made of a non-metallic material such as aluminum nitride (AlN), ceramics and quartz.

A heater 217b serving as a heating structure is integrally embedded in the susceptor 217. The heater 217b is configured to heat a surface of the wafer 200 to a temperature (for example, within a range from about 25° C. to about 750° C.) when an electric power is supplied to the heater 217b.

The susceptor 217 is electrically insulated from the lower vessel 211. An impedance adjusting electrode 217c is provided in the susceptor 217. The impedance adjusting electrode 217c is grounded via a variable impedance regulator 275 serving as an impedance adjusting structure. By changing (or varying) an impedance of the variable impedance regulator 275 within a predetermined range, it is possible to control an electric potential (bias voltage) of the wafer 200 (which is being processed by using the plasma) via the impedance adjusting electrode 217c and the susceptor 217.

A susceptor elevator 268 capable of elevating and lowering the susceptor 217 is provided below the susceptor 217. In addition, a plurality of through-holes 217a are provided at the susceptor 217, and a plurality of lift pins 266 serving as a support structure capable of supporting the wafer 200 are provided at a bottom surface of the lower vessel 211 at locations corresponding to the plurality of through-holes 217a. For example, at least three of the through-holes 217a and at least three of the lift pins 266 are provided at positions facing one another. When the susceptor 217 is lowered by the susceptor elevator 268, the lift pins 266 pass through and beyond the through-holes 217a without contacting the susceptor 217. Thereby, it is possible to hold (or support) the wafer 200 from thereunder by the lift pins 266.

### Gas Supplier

A gas supply head 236 is provided above the process chamber 201, that is, on an upper portion of the upper vessel 210. The gas supply head 236 may include a cap-shaped lid 233, a gas inlet port 234, a buffer chamber 237, an opening 238, a shield plate 240 and a gas outlet port 239, and is configured such that a gas is capable of being supplied into the process chamber 201 through the gas supply head 236. The buffer chamber 237 functions as a dispersion space in which the gas introduced (supplied) through the gas inlet port 234 is dispersed.

A downstream end of a gas supply pipe 232a through which a first gas is supplied, a downstream end of a gas supply pipe 232b through which a gas such as a helium (He)-containing gas is supplied and a downstream end of a gas supply pipe 232c through which a second gas is supplied are connected to a gas supply pipe 232 of the gas inlet port 234 so as to be conjoined with one another. For example, as the first gas, a nitrogen (N)-containing gas such as N₂ gas may be used. For example, as the second gas, a hydrogen (H)-containing gas such as H₂ gas may be used. A first gas supply source 250a, a mass flow controller (MFC) 252a serving as a flow rate controller and a valve 253a serving as an opening/closing valve are sequentially provided at the gas supply pipe 232a in this order from an upstream side to a downstream side of the gas supply pipe 232a in a gas flow direction. A helium-containing gas supply source 250b, an MFC 252b and a valve 253b are sequentially provided at the gas supply pipe 232b in this order from an upstream side to a downstream side of the gas supply pipe 232b in the gas flow direction. A second gas supply source 250c, an MFC 252c and a valve 253c are sequentially provided at the gas supply pipe 232c in this order from an upstream side to a downstream side of the gas supply pipe 232c in the gas flow direction. A valve 243a is provided at the gas supply pipe 232 at a downstream side of a location where the gas supply pipe 232a, the gas supply pipe 232b and the gas supply pipe 232c join. The valve 243a is connected to an upstream side of the gas inlet port 234. By opening and closing the valves 253a, 253b, 253c and 243a, it is possible to adjust flow rates of the first gas, the helium-containing gas and the second gas by the MFCs 252a, 252b and 252c, respectively. In addition, it is configured such that a process gas such as the first gas, the helium-containing gas and the second gas is capable of being supplied into the process chamber 201 through the gas supply pipe 232a, the gas supply pipe 232b or the gas supply pipe 232c.

A first gas supplier (which is a first gas supply structure or a first gas supply system) is constituted mainly by the gas supply head 236 (that is, the lid 233, the gas inlet port 234, the buffer chamber 237, the opening 238, the shield plate 240 and the gas outlet port 239), the gas supply pipe 232a, the MFC 252a, the valves 253a and 243a. In addition, a helium-containing gas supplier (which is a helium-containing gas supply structure or a helium-containing gas supply system) is constituted mainly by the gas supply head 236, the gas supply pipe 232b, the MFC 252b, the valves 253b and 243a. In addition, a second gas supplier (which is a second gas supply structure or a second gas supply system) is constituted mainly by the gas supply head 236, the gas supply pipe 232c, the MFC 252c, the valves 253c and 243a.

### Exhauster

A gas exhaust port 235 through which an inner atmosphere of the process chamber 201 is exhausted from the process chamber 201 is provided on a side wall of the lower vessel 211. An upstream end of a gas exhaust pipe 231 is connected to the gas exhaust port 235. An APC (Automatic Pressure Controller) valve 242 serving as a pressure regulator (pressure adjusting structure), a valve 243b and a vacuum pump 246 serving as a vacuum exhaust apparatus are sequentially provided at the gas exhaust pipe 231 in this order from an upstream side to a downstream side of the gas exhaust pipe 231 in the gas flow direction. An exhauster (which is an exhaust structure or an exhaust system) is constituted mainly by the gas exhaust port 235, the gas exhaust pipe 231, the APC valve 242 and the valve 243b. In addition, the exhauster may further include the vacuum pump 246.

### Plasma Generator

The resonance coil 212 of a spiral shape is provided on an outer periphery of the process chamber 201, that is, on an outside of a side wall of the upper vessel 210, so as to surround the process vessel 203. An RF (Radio Frequency) sensor 272, a high frequency power supply 273 and a frequency matcher (which is a frequency matching structure) 274 are connected to the resonance coil 212. The frequency matcher 274 may also be referred to as a “matcher 274” or a “frequency controller 274”. A shield plate 223 is provided on an outer periphery of the resonance coil 212.

The high frequency power supply 273 is configured to supply a high frequency power (RF power) to the resonance coil 212. The RF sensor 272 is provided at an output side of the high frequency power supply 273, and is configured to monitor information of a traveling wave or reflected wave of the high frequency power supplied from the high frequency power supply 273. Based on the information of the reflected wave monitored by the RF sensor 272, the frequency matcher 274 is configured to match (or adjust) a frequency of the high frequency power output from the high frequency power supply 273 so as to minimize the reflected wave.

Both ends of the resonance coil 212 are electrically grounded. A first end of the resonance coil 212 is grounded via a movable tap 213, and a second end of the resonance coil 212 is grounded via a fixed ground 214. In addition, a movable tap 215 is provided between the both ends of the resonance coil 212 such that a position at which the high frequency power is supplied from the high frequency power supply 273 can be set appropriately.

The shield plate 223 is configured to preventing an electromagnetic wave from leaking out of the resonance coil 212 by shielding an inside thereof from an electric field outside of the resonance coil 212, and to form a capacitive component appropriate for constructing a resonance circuit between the shield plate 223 and the resonance coil 212.

A plasma generator (which is a plasma generating structure) is constituted mainly by the resonance coil 212, the RF sensor 272 and the frequency matcher 274. The plasma generator may further include the high frequency power supply 273 and the shield plate 223.

Hereinafter, an operation of the plasma generator and the properties of the plasma generated accordingly will be further described below with reference to FIG. 2.

The resonance coil 212 is configured to function as a high frequency inductively coupled plasma (ICP) electrode. For example, a winding diameter, a winding pitch and the number of winding turns of the resonance coil 212 are set such that the resonance coil 212 resonates in a full-wavelength mode to form a standing wave of a predetermined wavelength. An electric length of the resonance coil 212 (that is, an electrode length between the grounds described above) is adjusted to an integral multiple of a wavelength of the frequency of the high frequency power supplied from the high frequency power supply 273. For example, parameters such as a configuration of the resonance coil 212, an electric power supplied to the resonance coil 212 and a strength of a magnetic field generated by the resonance coil 212 can be appropriately determined in consideration of, for example, an outer shape of the substrate processing apparatus 100 and contents of a processing. For example, an effective cross-section of the resonance coil 212 is set to a value within a range from 50 mm² to 300 mm², and a diameter of the resonance coil 212 is set to a value within a range from 200 mm to 500 mm. For example, the resonance coil 212 is wound twice to 60 times.

The high frequency power supply 273 includes a power supply controller (not shown) and an amplifier (not shown). The power supply controller is configured to output a predetermined high frequency signal (which is a control signal) to the amplifier based on output conditions related to the high frequency power or the frequency (which is set in advance through an operation panel). The amplifier is configured to output the high frequency power obtained by amplifying the control signal received from the power supply controller toward the resonance coil 212 via a transmission line. As described above, the RF sensor 272 is provided at an output side of the amplifier. The RF sensor 272 is configured to detect the power of the reflected wave in the transmission line and to feed-back a voltage signal related to the power of the reflected wave to the frequency matcher 274.

The frequency matcher 274 is configured to receive the voltage signal related to the power of the reflected wave from the RF sensor 272, and to perform a corrective control operation such as increasing or decreasing the frequency (oscillation frequency) of the high frequency power output by the high frequency power supply 273 such that the power of the reflected wave is minimized.

With such a configuration described above, an induction plasma of a desirable quality with almost no capacitive coupling with components such as an inner wall of the process chamber 201 and the susceptor 217 is excited in the plasma generation space 201a. That is, a donut-shaped plasma when viewed from above and with extremely low electric potential is generated in the plasma generation space 201a.

### Controller

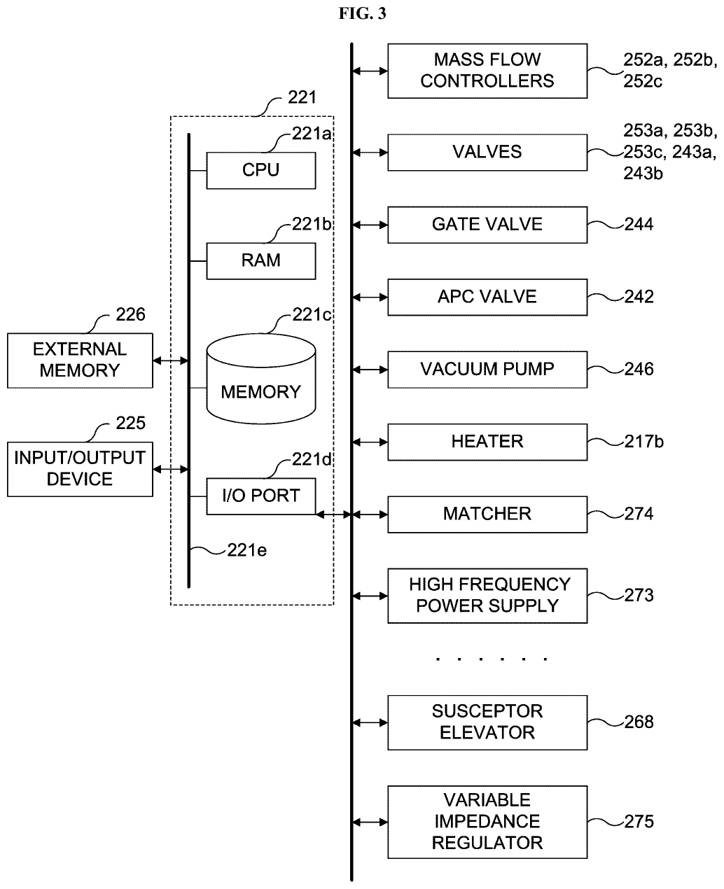

As shown in FIG. 3, a controller 221 serving as a control structure (control apparatus) is constituted by a computer including a CPU (Central Processing Unit) 221a, a RAM (Random Access Memory) 221b, a memory 221c and an I/O port (input/output port) 221d. The RAM 221b, the memory 221c and the I/O port 221d are configured to be capable of exchanging data with the CPU 221a through an internal bus 221e. For example, an input/output device 225 constituted by components such as a touch panel, a mouse, a keyboard and an operation terminal may be connected to the controller 221. For example, a display structure such as a display may be connected to the controller 221.

The memory 221c may be embodied by a component such as a flash memory, a hard disk drive (HDD) and a CD-ROM. For example, a control program configured to control operations of the substrate processing apparatus 100 and a process recipe in which information such as procedures and conditions of a substrate processing step described later is stored may be readably stored in the memory 221c. The process recipe is obtained by combining steps (procedures) of the substrate processing step described later such that the controller 221 can control the substrate processing apparatus 100 to execute the steps to acquire a predetermined result, and functions as a program. Hereinafter, the process recipe and the control program may be collectively or individually referred to as a “program”. Thus, in the present specification, the term “program” may refer to the process recipe alone, may refer to the control program alone, or may refer to both of the process recipe and the control program. Further, the RAM 221b functions as a memory area (work area) where a program or data read by the CPU 221a is temporarily stored.

The I/O port 221d is electrically connected to the components described above such as the MFCs 252a, 252b and 252c, the valves 253a, 253b and 253c, 243a and 243b, the gate valve 244, the APC valve 242, the vacuum pump 246, the heater 217b, the RF sensor 272, the high frequency power supply 273, the frequency matcher 274, the susceptor elevator 268 and the variable impedance regulator 275.

The CPU 221a is configured to read and execute the control program stored in the memory 221c, and to read the process recipe stored in the memory 221c in accordance with an instruction such as an operation command inputted via the input/output device 225. In addition, as shown in FIG. 1, the CPU 221a is configured to be capable of controlling various operations, in accordance with the read process recipe, such as: an operation of adjusting an opening degree of the APC valve 242, an opening and closing operation of the valve 243b and a start and stop of the vacuum pump 246 via the I/O port 221d and a signal line “A”; an elevating and lowering operation of the susceptor elevator 268 via the I/O port 221d and a signal line “B”; a power supply amount adjusting operation (temperature adjusting operation) to the heater 217b by a heater power regulator 276 based on a temperature sensor and an impedance value adjusting operation by the variable impedance regulator 275 via the I/O port 221d and a signal line “C”; an opening and closing operation of the gate valve 244 via the I/O port 221d and a signal line “D”; controlling operations for the RF sensor 272, the frequency matcher 274 and the high frequency power supply 273 via the I/O port 221d and a signal line “E”; and flow rate adjusting operations for various gases by the MFCs 252a, 252b and 252c and opening and closing operations of the valves 253a, 253b, 253c and 243a via the I/O port 221d and a signal line “F”.

For example, the controller 221 is not limited to a dedicated computer, and may be embodied by a general-purpose computer. For example, the controller 221 according to the present embodiments may be embodied by preparing an external memory 226 storing the program and by installing the program onto the general-purpose computer using the external memory 226. For example, the external memory 226 may include a magnetic tape, a magnetic disk such as a flexible disk and a hard disk, an optical disk such as a CD and a DVD, a magneto-optical disk such as an MO and a semiconductor memory such as a USB memory and a memory card. For example, a method of providing the program to the computer is not limited to that using the external memory 226. For example, the program may be supplied to the computer (general-purpose computer) using a communication interface such as the Internet and a dedicated line without the external memory 226 interposed therebetween. According to the present embodiments, the memory 221c or the external memory 226 may be embodied by a non-transitory computer readable recording medium. Hereafter, the memory 221c and the external memory 226 may be collectively or individually referred to as a “recording medium”. Thus, in the present specification, the term “recording medium” may refer to the memory 221c alone, may refer to the external memory 226 alone, or may refer to both of the memory 221c and the external memory 226.

### (2) Processing Step

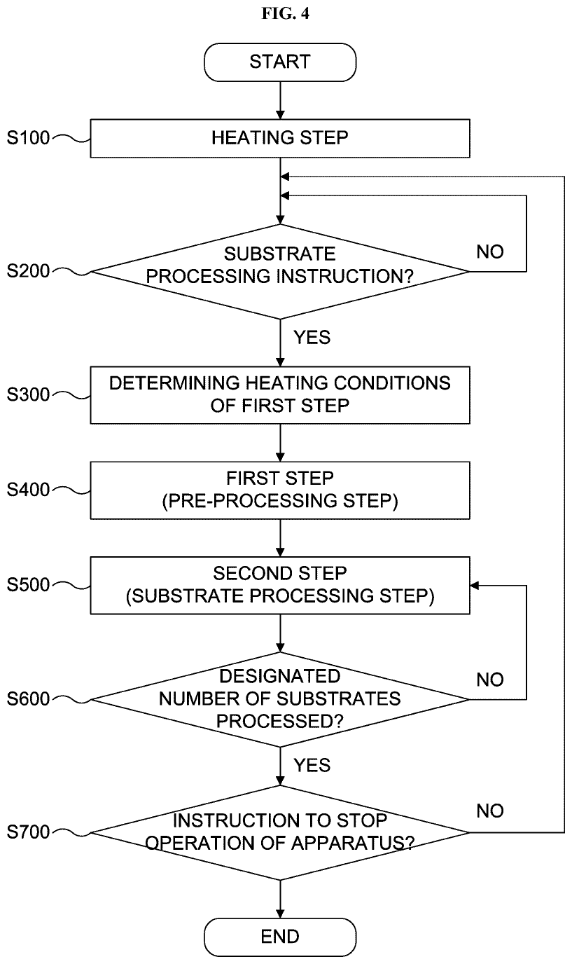

Subsequently, an example of a process sequence of a processing step (which is a part of a manufacturing process of a semiconductor device) of performing a modification process on a film formed on the surface of the wafer 200 will be described mainly with reference to FIGS. 4 to 6. The processing step is performed by using the substrate processing apparatus 100 described above. In the following description, operations of the components constituting the substrate processing apparatus 100 are controlled by the controller 221.

According to the process sequence of the processing step of the present embodiments, a first step of heating the process vessel 203 with a predetermined thermal gradient without loading the wafer 200 in the process vessel 203 is performed, and after the first step, a second step of processing the wafer 200 with the wafer 200 loaded in the process vessel 203 is performed.

The present embodiments will be described by way of an example in which, in the first step, the first gas is supplied into the process vessel 203, and a first electric power is input (supplied) to the resonance coil 212 serving as an electrode to excite the first gas into a plasma state and to heat the process vessel 203.

The present embodiments will be described by way of an example in which, in the second step, the first gas is supplied into the process vessel 203, and a second electric power is applied (supplied) to the resonance coil 212 serving as the electrode to excite the first gas into the plasma state and to process the wafer 200.

As shown in FIG. 4, the processing step according to the present embodiments mainly includes the first step (also referred to as a “pre-processing step”) S400 of performing a heating process for the process vessel 203, and the second step (that is, the substrate processing step) S500 of processing the wafer 200. The processing step according to the present embodiments will be described below.

### (2-1) Heating Step (S100)

First, the electric power is supplied to the heater 217b to start heating the susceptor 217. The heater 217b is controlled such that a temperature of the susceptor 217 measured by a temperature sensor (not shown) reaches and is maintained at a predetermined temperature. Then, the heater 217b continuously heat the susceptor 217 until an entirety of steps of the processing step are completed.

### (2-2) Idling Step (Step of Waiting for Substrate Processing Instruction) (S200)

In the present step, the substrate processing apparatus 100 is in an instruction waiting state (idling state) waiting for an instruction to process the wafer 200 (that is, an instruction to perform the second step). The instruction to process the wafer 200 may also be referred to as a “substrate processing instruction”. The idling state is a state in which the susceptor 217 is maintained at a predetermined temperature while waiting for the substrate processing instruction. For example, the idling state may occur, between an end of processing the wafer 200 (that is, after the wafer (which is processed) 200 is unloaded out of the process vessel 203) and a start of processing a subsequent wafer 200 (that is, before the start of processing the subsequent wafer 200), or between an end of processing a previous lot (group of substrates) and a start of processing a subsequent lot. Depending on a timing of the substrate processing instruction, a time duration of the idling state (that is, a length of the idling step S200, an idling time or a waiting time) may vary. In the present step, it is determined whether the substrate processing instruction has been input. When the substrate processing instruction has not been input, such a determination is performed again at regular intervals. When the substrate processing instruction has been input, a subsequent step, that is, a step S300 is performed. In the substrate processing instruction, an instruction for the number of wafers 200 to be processed in the second step (that is, the number of times the second step is to be performed) is also input.

### (2-3) Step of Determining Heating Conditions of First Step (S300)

In the present step, the time (waiting time) of the idling step S200 is checked, and heating conditions of the process vessel 203 in a subsequent step (that is, the first step S400) are determined in accordance with the time.

### (2-4) First Step (Pre-Processing Step) (S400)

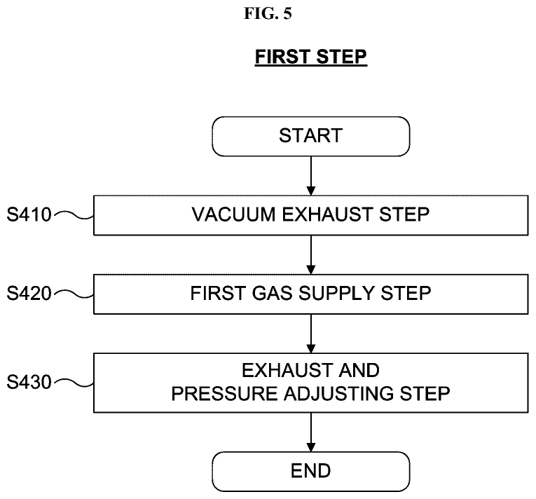

In the present step, the process vessel 203 is heated as a pre-processing for a subsequent step (that is, the second step S500). Each step constituting the first step S400 will be described below mainly with reference to FIG. 5. The first step S400 may be performed with a dummy substrate placed on the susceptor 217. However, the first step S400 will be described by way of an example in which the dummy substrate is not used.

### Vacuum Exhaust Step S410

First, the inner atmosphere of the process chamber 201 is evacuated (vacuum-exhausted) by the vacuum pump 246 such that a pressure (inner pressure) of the process chamber 201 reaches and is maintained at a predetermined pressure. The vacuum pump 246 is continuously operated at least until an exhaust and pressure adjusting step S430 described later is completed.

### First Gas Supply Step S420

In the present step, the first gas is excited into the plasma state and supplied into the process vessel 203.

Specifically, the valve 253a is opened to supply the first gas into the gas supply pipe 232a. A flow rate of the first gas is adjusted by the MFC 252a. The first gas whose flow rate is adjusted is supplied into the process chamber 201 via the buffer chamber 237, and is exhausted through the exhaust port 235. Thereby, the first gas is supplied into the process vessel 203 (first gas supply).

In such a state, the radio frequency (RF) power is supplied from the high frequency power supply 273 to the resonance coil 212. As a result, the first gas is discharged intensively in the plasma generation space 201a, particularly at height positions of an upper end, a middle point and the lower end of the resonance coil 212. That is, a plasma discharge is generated. By the plasma discharge generated in a manner described above, the process vessel 203 can be heated from the inside thereof. In particular, portions of the process vessel 203 corresponding to the height positions mentioned above where the plasma discharge is generated intensively and peripheries thereof are heated intensively. According to the present embodiments, the resonance coil 212 may also be referred to as a “heating element” or a “heater”. The RF power is continuously supplied to the resonance coil 212 at least until the second step S500 described later is completed.

By heating the process vessel 203 under predetermined process conditions, it is possible to increase (elevate) an inner temperature of the process vessel 203 to a predetermined temperature.

The heating conditions in this step are set corresponding to (in accordance with) the time (waiting time) of the idling step S200. When the time of the idling step S200 is relatively short (that is, shorter than a predetermined time), the RF power is set to be higher than a predetermined electric power. When the time of the idling step S200 is relatively long (that is, longer than the predetermined time) the RF power is set to be relatively low.

By setting the heating conditions as described above, a temperature increase rate (temperature elevation rate) per unit time in the process vessel 203 (that is, a thermal gradient) can be varied (changed) in accordance with the time of the idling step S200. Specifically, when the time of the idling step S200 is relatively short, the thermal gradient is set to be relatively steep, and when the time of the idling step S200 is relatively long, the thermal gradient set to be relatively mild (hereinafter, the thermal gradients mentioned above may be collectively or individually referred to as the “predetermined thermal gradient”). That is, when the time of the idling step S200 is shorter than the predetermined time, the process vessel 203 is heated with a first thermal gradient, and when the time of the idling step S200 is longer than the predetermined time, the process vessel 203 is heated with a second thermal gradient smaller than the first thermal gradient.

As the first gas, for example, the nitrogen-containing gas may be used. As the nitrogen-containing gas, for example, instated of or in addition to the N₂ gas, a hydrogen nitride-based gas such as ammonia (NH₃) gas, diazene (N₂H₂) gas, hydrazine (N₂H₄) gas and N₃H₈ gas may be used. In addition, as the nitrogen-containing gas, for example, one or more of the gases exemplified above may be used. In addition, the nitrogen-containing gas, for example, a gaseous mixture of the nitrogen-containing gas and the hydrogen-containing gas (such as a gaseous mixture of the N₂ gas and the H₂ gas) may be used.

When the inner temperature of the process vessel 203 reaches and is maintained at a desired temperature, a supply of the first gas into the process vessel 203 is stopped.

### Exhaust and Pressure Adjusting Step S430

The gas remaining in the process chamber 201 is exhausted out of the process chamber 201. Thereafter, the opening degree of the APC valve 242 is adjusted such that the inner pressure of the process chamber 201 is set to be substantially the same as that of a vacuum transfer chamber (not shown).

### (2-5) Second Step (Substrate Processing Step) (S500)

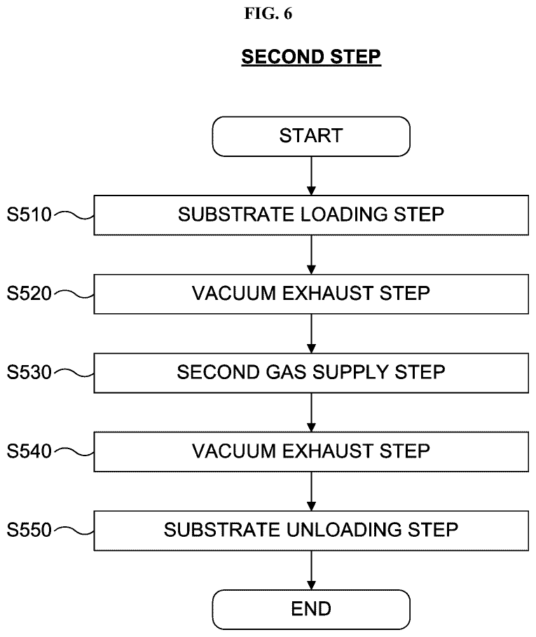

In the present step, for example, a nitriding plasma process serving as the modification process is performed on a silicon film (Si film) (which serves as the film formed on the surface of the wafer 200) to form a silicon nitride film (SiN film). Each step constituting the second step S500 will be described below mainly with reference to FIG. 6.

### Substrate Loading Step S510

The susceptor elevator 268 lowers the susceptor 217 such that the lift pins 266 protrude a predetermined height from a surface of the susceptor 217. Subsequently, the wafer 200 is transferred onto the lift pins 266 from the vacuum transfer chamber adjacent to the process chamber 201 using a wafer transfer structure (not shown). Thereafter, the susceptor elevator 268 elevates the susceptor 217 to a predetermined position between the lower end of the resonance coil 212 and an upper end 245a of the loading/unloading port 245. Thereby, the wafer 200 is supported on an upper surface of the susceptor 217. In addition, in the present step, the electric power supplied to the resonance coil 212 may be changed to be greater than the first electric power.

### Vacuum Exhaust Step S520

In the present step, for example, the inner atmosphere of the process chamber 201 is evacuated (vacuum-exhausted) by the vacuum pump 246 via the exhaust pipe 231 such that the inner pressure of the process chamber 201 reaches and is maintained at a predetermined pressure.

### Second Gas Supply Step S530

In the present step, the first gas is excited into the plasma state and supplied to the wafer 200 in the process chamber 201.

Specifically, the valve 253a is opened to supply the first gas into the gas supply pipe 232a. The flow rate of the first gas is adjusted by the MFC 252a. The first gas whose flow rate is adjusted is supplied into the process chamber 201 via the buffer chamber 237, and is exhausted through the exhaust port 235. Thereby, the first gas is supplied to the wafer 200 from above the wafer 200 (first gas supply). In the present step, the valve 253c may be opened to further supply the second gas into the process chamber 201 via the buffer chamber 237.

In the present step, the radio frequency (RF) power is applied (supplied) from the high frequency power supply 273 to the resonance coil 212. As a result, a donut-shaped induction plasma when viewed from above is excited (generated) at height positions in the plasma generation space 201a corresponding to grounded points (that is, the upper end and the lower end) and an electric midpoint of the resonance coil 212. By exciting the induction plasma, for example, when the nitrogen-containing gas is used as the first gas, the nitrogen-containing gas is activated to generate a nitriding species. The nitriding species includes one or both of an excited nitrogen atom (N*) and an ionized nitrogen atom. In the present specification, the symbol “*” indicates a radical. This also applies to the following descriptions. For example, when a gas further containing hydrogen in addition to nitrogen is used as the nitrogen-containing gas or when the hydrogen-containing gas is supplied as the second gas together with the nitrogen-containing gas, the nitriding species further includes one or both of an excited NH group (NH*) and an ion containing nitrogen and hydrogen. Further, in such a case, a reactive species such as an excited hydrogen atom (H*) and an ionized hydrogen atom may also be generated. Such a reactive species may also be considered as a part of the nitriding species.

The nitrogen-containing gas is excited by the plasma and supplied to the wafer 200 under predetermined process conditions. Thereby, the nitriding species is supplied to the surface of the wafer 200. By the nitriding species supplied to the surface of the wafer 200, at least a part of the silicon film formed on the surface of the wafer 200 is modified to the silicon nitride film.

In the present step, the nitriding species is also supplied to an inner wall of the process vessel 203. Thus, for example, when the process vessel 203 is made of silicon oxide (SiO₂), a surface of the inner wall of the process vessel 203 may be modified to silicon oxynitride (SiON). As described above, there are locations in the process vessel 203 where the plasma discharge is generated intensively, and the surface of the inner wall of the process vessel 203 undergoes denser modification at such locations than at the other locations. As such, a local variation in a nitriding state occurs on the surface of the inner wall of the process vessel 203, which also causes a local variation in a stress on the surface of the inner wall of the process vessel 203. Therefore, for example, when a temperature of the inner wall of the process vessel 203 is elevated rapidly from a low temperature by generating the plasma discharge in the substrate processing step, the inner wall of the process vessel 203 may be peeled off and may generate particles. However, according to the present embodiments, by performing the first step of heating the process vessel 203 to the predetermined temperature before performing the present step, it is possible to prevent the temperature of the inner wall of the process vessel 203 from rapidly elevating from a low temperature to a high temperature in the present step. Thereby, it is possible to prevent the particles from being generated.

After a predetermined processing time has elapsed, an output of the electric power from the high frequency power supply 273 is stopped to stop the plasma discharge in the process chamber 201. Further, the supply of the first gas into the process chamber 201 is stopped. A supply of the second gas is also stopped in case of the second gas being used together with the first gas.

### Vacuum Exhaust Step S540

The inner atmosphere of the process chamber 201 such as the first gas in the process chamber 201 is evacuated (vacuum-exhausted) out of the process chamber 201 via the gas exhaust pipe 231. Thereafter, the opening degree of the APC valve 242 is adjusted such that the inner pressure of the process chamber 201 is set to be substantially the same as that of the vacuum transfer chamber adjacent to the process chamber 201.

### Substrate Unloading Step S550

After the inner pressure of the process chamber 201 is adjusted to a predetermined pressure, the susceptor 217 is lowered to a transfer position of the wafer 200 until the wafer 200 is supported by the lift pins 266. Then, the wafer 200 supported by the lift pins 266 is transferred (unloaded) out of the process chamber 201 by using the wafer transfer structure. Thereby, the second step S500 is completed.

### (2-6) Step of Determining Number of Executions Repeatedly Performed (S600)

After the second step S500 is completed, referring to the number of the wafers 200 to be processed (which is input during the idling step S200), it is determined whether a designated number of substrates (wafers 200) are processed (that is, the second step S500 is repeatedly performed corresponding to the number of the wafers 200). When it is determined that a processing of the designated number of substrates (wafers 200) is completed, a subsequent step (that is, a step S700) is performed. When it is determined that the processing of the designated number of substrates (wafers 200) is not completed, the second step S500 is performed again on another wafer among the wafers 200.

### (2-7) Determining Whether to Stop Operation of Apparatus (S700)

After the step S600 (that is, after performing the step of determining the number of the executions of the second step S500 repeatedly performed) is completed, when an instruction to stop the operation of the substrate processing apparatus 100 is input, the operation of the substrate processing apparatus 100 is stopped and the processing step is completed. When the instruction to stop the operation of the substrate processing apparatus 100 is not input, the idling step S200 and subsequent steps are performed again.

(3) Effects according to Present Embodiments

According to the present embodiments, it is possible to obtain one or more of the following effects.

(a) Before the second step S500 is started, the first step S400 is performed to heat (pre-heat) the inside of the process vessel 203 in advance. Thereby, it is possible to prevent the inner temperature of the process vessel 203 from being elevated rapidly in the second step S500, and it is also possible to prevent the particles from being generated. Further, in the first step S400, the process vessel 203 is heated with the predetermined thermal gradient to prevent the temperature of the inner wall of the process vessel 203 from being elevated rapidly from the low temperature to the high temperature. Thereby, it is also possible to prevent (or suppress) the particles from being generated in the first step S400.

(b) By setting the predetermined thermal gradient in accordance with the heating conditions corresponding to the time (waiting time) of the idling step S200, it is possible to reliably prevent the temperature of the inner wall of the process vessel 203 from being elevated rapidly from the low temperature to the high temperature in the first step S400, and it is also possible to prevent the particles from being generated in the first step S400.

Specifically, for example, when the time (waiting time) of the idling step S200 is relatively short, the RF power is set to be relatively high, and when the time (waiting time) of the idling step S200 is relatively long, the RF power is set to be relatively low. By setting the heating conditions in a manner described above, when the time of the idling step S200 is relatively short, the thermal gradient is set to be relatively steep, and when the time of the idling step S200 is relatively long, the thermal gradient is set to be relatively mild. Thereby, it is possible to reliably obtain the effects mentioned above.

For example, as the time (waiting time) of the idling step S200 becomes longer, the inner temperature of the process vessel 203 (which is heated in the heating step S100) may gradually decrease. In the first step S400, for example, when the nitrogen-containing gas is supplied as the first gas into the process chamber 201, the inner wall of the process vessel 203 is nitrided. However, as described above, a local variation in the nitriding state occurs on the surface of the inner wall of the process vessel 203, which also causes a local variation in the stress on the surface of the inner wall of the process vessel 203. Therefore, when the temperature of the inner wall of the process vessel 203 is elevated rapidly from the low temperature to the high temperature in the first step S400, the inner wall may be peeled off and may generate the particles in the process vessel 203.

When the time (waiting time) of the idling step S200 is relatively long, the inner temperature of the process vessel 203 is relatively low at a start of the first step S400, and thus the particles may be generated when the inner temperature of the process vessel 203 is elevated rapidly. According to the present embodiments, in such a case, since the heating conditions are determined based on data on the inner temperature of the process vessel 203 (which is created in advance) corresponding to the time of the idling step S200 such that the thermal gradient is set to be relatively mild, the inner temperature of the process vessel 203 is elevated slowly. Thereby, it is possible to prevent the particles from being generated in the process vessel 203.

On the other hand, when the time (waiting time) of the idling step S200 is relatively short, the inner temperature of the process vessel 203 is maintained to be relatively high at the start of the first step S400. According to the present embodiments, in such a case, the heating conditions are determined based on data on the inner temperature of the process vessel 203 (which is created in advance) corresponding to the time of the idling step S200 such that the thermal gradient is relatively steep. Therefore, the inner temperature of the process vessel 203 is elevated rapidly. Even with such a thermal gradient, the particles are less likely to be generated. This is because the inner temperature of the process vessel 203 is maintained at a relatively high temperature at the start of the first step S400 so that the temperature of the inner wall of the process vessel 203 is not elevated so rapidly. By applying such a thermal gradient, it is also possible to improve the throughput.

By varying the thermal gradient in accordance with the time of the idling step S200, it is possible to reliably prevent the particles from being generated in the process vessel 203.

(c) In the second step S500, by applying (supplying) the second electric power (which is greater than the first electric power applied in the first step S400) to the resonance coil 212, it is possible to elevate (increase) the inner temperature of the process vessel 203 to a desired substrate processing temperature in a short time. Thereby, it is possible to prevent the particles from being generated in the process vessel 203, and it is also possible to improve the throughput.

(d) Once an electric power application state in which the electric power is supplied to the resonance coil 212 is started in the first step S400, the electric power application state can be maintained even while performing the second step S500. Thereby, it is possible to avoid a repetition of applying and stopping the electric power, so that it is also possible to further improve the throughput.

### Other Embodiments of Present Disclosure

While the technique of the present disclosure is described in detail by way of the embodiments mentioned above, the technique of the present disclosure is not limited thereto. The technique of the present disclosure may be modified in various ways without departing from the scope thereof.

For example, the embodiments mentioned above are described by way of an example in which a constant electric power (first electric power) is supplied (input) to the resonance coil 212 in the first step S400. However, the technique of the present disclosure is not limited thereto. For example, the electric power supplied to the resonance coil 212 may be changed (increased) stepwise in accordance with an increase (elevation) in the inner temperature of the process vessel 203. By changing (increasing) the electric power supplied to the resonance coil 212, the inner temperature of the process vessel 203 is elevated rapidly. However, such a rapid increase (elevation) occurs after the inner temperature of the process vessel 203 is elevated to a predetermined temperature. Thereby, it is possible to prevent the particles from being generated in the process vessel 203. In addition, by changing the electric power supplied to the resonance coil 212, it is also possible to improve the throughput. Further, a change in the electric power supplied to the resonance coil 212 is not limited to the two-staged change mentioned above. That is, the electric power supplied to the resonance coil 212 may be changed in multiple stages.

For example, the embodiments mentioned above are described by way of an example in which the nitrogen-containing gas is used as the first gas. However, the technique of the present disclosure is not limited thereto. For example, instead of the first gas, helium (He) gas or the H₂ gas may be used. For example, the inner temperature of the process vessel 203 tends to increase more easily when using the helium gas or the H₂ gas as compared with a case where the N₂ gas is used. In the first step S400, the kind of gas may be selected based on the specific situations such as the following examples: the helium gas or the H₂ gas may be used when it is preferable to rapidly increase the inner temperature of the process vessel 203; and the N₂ gas may be used when it is preferable to gradually increase the inner temperature of the process vessel 203. Even in such a modified example, it is possible to obtain substantially the same effects as those of the embodiments mentioned above. In addition, when the helium gas or the H₂ gas is used to heat the process vessel 203, each of the helium gas and the H₂ gas may also be referred to as a “heating medium gas”. Further, when such a heating medium gas is used in the first step S400, a gas (for example, the nitrogen-containing gas) whose primary constituent (main constituent) is different from that of the heating medium gas may be used in the second step S500.

For example, the embodiments mentioned above are described by way of the example in which the nitrogen-containing gas is used as the first gas. However, the technique of the present disclosure is not limited thereto. For example, as the first gas, instead of the nitrogen-containing gas, a gaseous mixture of the N₂ gas and the helium gas or the gaseous mixture of the N₂ gas and the H₂ gas may be used. For example, when the gaseous mixture of the N₂ gas and the helium gas is used as the first gas, the inner temperature of the process vessel 203 tends to increase more easily as compared with a case where the N₂ gas is used. Therefore, for example, when it is preferable to heat quickly in the first step S400 or when it is preferable to heat efficiently with a small supply of the electric power, such a gaseous mixture may be used. With such a configuration, it is possible to more reliably prevent (or suppress) the particles from being generated.

For example, the embodiments mentioned above are described by way of the example in which the nitrogen-containing gas is used as the first gas. However, the technique of the present disclosure is not limited thereto. For example, as described above, instead of the first gas, the helium gas or the H₂ gas may be used. In such a case, for example, various gases may be selected in accordance with the idling time (waiting time). Thereby, it is possible to perform a highly flexible operation considering a heating efficiency and a heating time.

For example, the embodiments mentioned above are described by way of the example in which the nitrogen-containing gas is used as the first gas. However, the technique of the present disclosure is not limited thereto. For example, as described above, instead of the first gas, the helium gas or the H₂ gas may be used. In such a case, for example, the electric power to be supplied may be set in accordance with a type of the gas supplied in a manner described above. Specifically, an electric power (which is smaller than the predetermined electric power) is supplied for a gas with a relatively strong excitation energy (for example, the helium gas), and an electric power (which is greater than the predetermined electric power) is supplied for a gas with a relatively weak excitation energy (for example, the H₂ gas). Thereby, it is possible to efficiently heat the process vessel 203 while preventing the gas from being activated beyond a desired state and from etching the inner wall of the process vessel 203.

For example, the embodiments mentioned above are described by way of the example in which the predetermined thermal gradient is set in accordance with the heating conditions corresponding to the time (waiting time) of the idling step S200. However, the technique of the present disclosure is not limited thereto. For example, in the step S300 of determining the heating conditions of the first step S400, the inner temperature of the process vessel 203 at the start of the first step S400 may be actually measured, and the heating conditions of the process vessel 203 in the first step S400 may be determined in accordance with the temperature actually measured. The predetermined thermal gradient may be set in accordance with the heating conditions corresponding to the temperature actually measured. Even in such a modified example, it is possible to obtain substantially the same effects as those of the embodiments mentioned above.

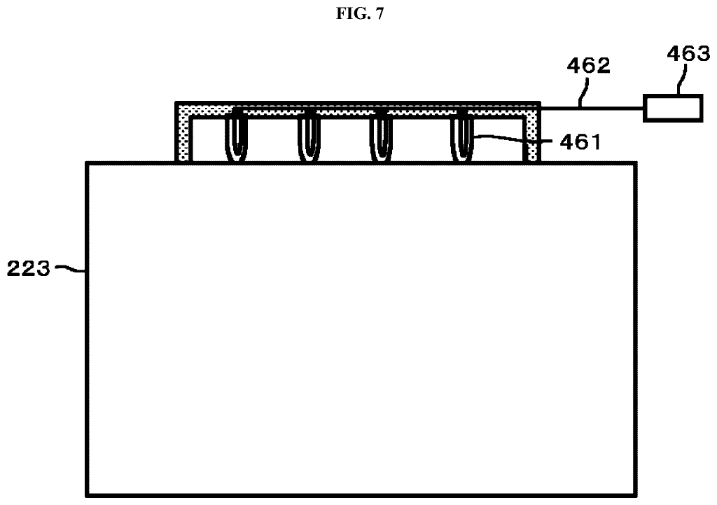

For example, the embodiments mentioned above are described by way of the example in which the first gas is excited into the plasma state to heat the process vessel 203 from the inside thereof in the first step S400. However, the technique of the present disclosure is not limited thereto. For example, as shown in FIG. 7, the process vessel 203 may be heated from an outside thereof by a plurality of lamp heaters 461 arranged in the vicinity of a ceiling of the shield plate 223. The lamp heaters 461 serve as a heating structure (or a heater). Even in such a modified example, it is possible to obtain substantially the same effects as those of the embodiments mentioned above. The lamp heaters 461 are connected to a lamp controller 463 via a wiring 462. For example, an operation such as a supply of an electric power and a turn-on and turn-off (ON/OFF) operation of the lamp heaters 461 may be controlled by the lamp controller 463 based on an instruction from the controller 221. For convenience, in FIG. 7, a state where the lamp heaters 461 are provided in the vicinity of the ceiling of the shield plate 223 is shown. Since other components of the substrate processing apparatus 100 shown in FIG. 7 are similar to those of the substrate processing apparatus 100 shown in FIG. 1, illustration thereof is omitted from FIG. 7.

For example, the embodiments mentioned above are described by way of the example in which the first gas is excited into the plasma state to heat the process vessel 203 in the first step S400. However, the technique of the present disclosure is not limited thereto. For example, a small amount of the electric power that is not sufficient to excite the first gas into the plasma state may be supplied (applied) to the resonance coil 212, and the inside of the process vessel 203 may be heated by a dielectric heating. Even in such a modified example, it is possible to obtain substantially the same effects as those of the embodiments mentioned above. In addition, in the present modified example, for example, when the time (waiting time) of the idling step S200 is long (for example, 35 hours), by heating the inside of the process vessel 203 by the dielectric heating, it is possible to elevate (increase) the inner temperature of the process vessel 203 more slowly as compared with a case where the inner temperature of the process vessel 203 is elevated according to the embodiments mentioned above.

For example, the embodiments mentioned above are described by way of the example in which the first step S400 is performed while neither the wafer 200 nor the dummy substrate serving as a dummy for the wafer 200 is placed on the susceptor 217. However, the technique of the present disclosure is not limited thereto. For example, the first step may be performed while the dummy substrate is placed on the susceptor 217. Even in such a modified example, it is possible to obtain substantially the same effects as those of the embodiments mentioned above. In addition, in such a modified example, sometimes it may be possible to obtain more preferable effects than those of the embodiments mentioned above.

According to the embodiments mentioned above, the first step S400 is performed without placing the wafer 200 on the susceptor 217, and then the second step S500 is performed with the wafer 200 placed on the susceptor 217. Therefore, in the second step S500, the heater 217b is blocked from the inner wall of the process vessel 203 by the wafer 200. As a result, in the second step S500, the temperature of the inner wall of the process vessel 203 may decrease (be lowered) rapidly. Thereby, the particles may be generated. Thus, in the present modified example, the first step S400 is performed with the dummy substrate placed on the susceptor 217. By placing the dummy substrate between the heater 217b and the inner wall of the process vessel 203 in the first step S400, it is possible to reduce an effect of the heat radiated from the heater 217b. As a result, it is possible to prevent a rapid decrease in the temperature of the inner wall of the process vessel 203 in the second step S500, and therefore it is possible to reliably prevent the particles from being generated.

For example, the embodiments mentioned above are described by way of the example in which the nitrogen-containing gas is supplied onto the wafer 200 to form the silicon nitride film in the second step S500. However, the technique of the present disclosure is not limited thereto. For example, an oxygen (O)-containing gas may be supplied onto the wafer 200 to form a silicon oxide film (SiO film). This can also achieve the advantageous effects same as those of the aforementioned embodiments.

It is preferable that recipes used in processes are prepared individually in accordance with contents of the processes and stored in the memory 221c via an electric communication line or the external memory 226. When starting each process, it is preferable that the CPU 221a selects an appropriate recipe among the recipes stored in the memory 221c in accordance with the contents of each process. Thus, various films of different composition ratios, qualities and thicknesses can be formed in a reliably reproducible manner by using a single substrate processing apparatus (that is, the substrate processing apparatus 100 described above). In addition, since a burden on an operating personnel can be reduced, various processes can be performed quickly while avoiding an error in operating the substrate processing apparatus 100.

The recipe described above is not limited to creating a new recipe. For example, the recipe may be prepared by changing an existing recipe stored (or installed) in the substrate processing apparatus 100 in advance. When changing the existing recipe to a new recipe, the new recipe may be installed in the substrate processing apparatus 100 via the electric communication line or a recording medium in which the new recipe is stored. Further, the existing recipe already stored in the substrate processing apparatus 100 may be directly changed to the new recipe by operating the input/output device 225 of the substrate processing apparatus 100.

For example, the embodiments mentioned above are described by way of an example in which a single wafer type substrate processing apparatus configured to process one substrate at a time is used. However, the technique of the present disclosure is not limited thereto. For example, the technique of the present disclosure may be preferably applied when a batch type substrate processing apparatus configured to process a plurality of substrates at a time is used.

The process procedures and the process conditions of each process using the substrate processing apparatuses exemplified above may be substantially the same as those of the embodiments mentioned above. Even in such a case, it is possible to obtain substantially the same effects as in the embodiments mentioned above.

Further, the embodiments and the modified examples mentioned above may be appropriately combined. The process procedures and the process conditions of each combination thereof may be substantially the same as those of the embodiments mentioned above.

As described above, according to some embodiments of the present disclosure, it is possible to suppressing a generation of particles in a process vessel.

What is claimed is:

1. A substrate processing method comprising:
(a) heating a process vessel with a predetermined thermal gradient without loading a process substrate in the process vessel; and
(b) processing the process substrate after (a) with the process substrate loaded in the process vessel.

2. The substrate processing method of claim 1, further comprising
(c) waiting for an instruction to process the process substrate before (a),
wherein the predetermined thermal gradient is set in accordance with heating conditions corresponding to a waiting time of (c).

3. The substrate processing method of claim 2, wherein, in (a), the process vessel is heated with a first thermal gradient when the waiting time of (c) is shorter than a predetermined time, and the process vessel is heated with a second thermal gradient smaller than the first thermal gradient when the waiting time of (c) is longer than the predetermined time.

4. The substrate processing method of claim 1, wherein, in (a), the process vessel is heated by supplying a first gas or a heating medium gas into the process vessel and applying a first electric power to an electrode provided outside the process vessel to excite the first gas or the heating medium gas into a plasma state.

5. The substrate processing method of claim 4, wherein the first electric power applied to the electrode is set in accordance with a type of the first gas or the heating medium gas supplied into the process vessel.

6. The substrate processing method of claim 4, wherein, in (b), the process substrate is processed by supplying the first gas into the process vessel and applying a second electric power greater than the first electric power to the electrode to excite the first gas into the plasma state.

7. The substrate processing method of claim 2, wherein in (a), a first electric power applied to an electrode provided outside the process vessel is set to be greater when the waiting time of (c) is shorter than a predetermined time than when the waiting time of (c) is longer than the predetermined time.

8. The substrate processing method of claim 1, wherein, in (a), the process vessel is heated by applying an electric power to a lamp heater provided outside the process vessel.

9. The substrate processing method of claim 1, wherein (a) is performed with a dummy substrate placed on a substrate mounting table provided in the process vessel.

10. The substrate processing method of claim 9, wherein the dummy substrate is disposed between a heater embedded in the substrate mounting table and an inner wall of the process vessel.

11. The substrate processing method of claim 4, wherein the first electric power is changed stepwise.

12. The substrate processing method of claim 1, wherein, in (a), the process vessel is heated by supplying a first gas into the process vessel and applying an electric power to an electrode provided outside the process vessel, and
wherein the electric power is set to be smaller than an electric power level capable of exciting the first gas into a plasma state.

13. The substrate processing method of claim 4, wherein, once an electric power application state in which the first electric power is supplied to the electrode is started in the (a), the electric power application state is maintained even while performing (b).

14. The substrate processing method of claim 1, wherein a heating medium gas is supplied in (a).

15. The substrate processing method of claim 14, wherein the heating medium gas comprises a hydrogen-containing gas or a helium-containing gas.

16. The substrate processing method of claim 14, wherein a first gas whose primary constituent is different from that of the heating medium gas is supplied in (b).

17. The substrate processing method of claim 1, wherein an inner wall of the process vessel is not peeled off at the predetermined thermal gradient.

18. A method of manufacturing a semiconductor device, comprising:
the method of claim 1.

19. A non-transitory computer-readable recording medium storing a program that causes a substrate processing apparatus, by a computer, to perform:
(a) heating a process vessel with a predetermined thermal gradient without loading a process substrate in the process vessel; and
(b) processing the process substrate after (a) with the process substrate loaded in the process vessel.

20. A substrate processing apparatus comprising:
a process vessel in which a process substrate is processed;
a heater configured to heat the process vessel;
a gas supplier configured to supply a gas to the process substrate in the process vessel; and
a controller configured to be capable of controlling the heater and the gas supplier to perform:
(a) heating the process vessel with a predetermined thermal gradient without loading the process substrate in the process vessel; and
(b) processing the process substrate after (a) with the process substrate loaded in the process vessel.
